(19) United States
(12) Patent Application Publication
(10) Pub. No.: US 2018/0016702 A1
(43) Pub. Date: Jan. 18, 2018

(54) METHOD FOR GROWING MONOCRYSTALLINE SILICON BY USING CZOCHRALSKI METHOD

(71) Applicant: ZING SEMICONDUCTOR CORPORATION, Shanghai (CN)

(72) Inventors: DEYUAN XIAO, Shanghai (CN); RICHARD R. CHANG, Shanghai (CN)

(21) Appl. No.: 15/392,118

(22) Filed: Dec. 28, 2016

(30) Foreign Application Priority Data
Jul. 12, 2016 (CN) 201610544093.3

(51) Int. Cl. C30B 15/04; C30B 30/04; C30B 29/06

(52) U.S. Cl. CPC C30B 15/04; C30B 29/06; C30B 30/04

(57) ABSTRACT

The present application provides a method for growing monocrystalline silicon by using Czochralski method, comprising: step (1) melting a deuterium-, nitrogen- and barium-doped silicon sheet and a polycrystalline silicon in a crucible; step (2) forming a deuterium- and nitrogen-doped monocrystalline silicon ingot by using magnetic field-applied Czochralski method. The impurity level of the melt and the grown crystal can be reduced according to the present application. By applying rapid thermal annealing to the nitrogen-doped monocrystalline silicon sheet, crystal originated particle defects in surface area of the silicon sheet can be eliminated. The storage of deuterium atoms in gaps of the silicon sheet is able to reduce the contents of oxygen and carbon impurities. Moreover, the deuterium atoms can bind with dangling bonds at the interface between the gate dielectric layer and the semiconductor to form a stable structure, thereby penetration of hot carriers can be prevented, leakage current can be reduced, and device properties and reliability can be enhanced. While the silicon sheet is doped with deuterium, nitrogen and barium, the amount of the doped silicon sheet applied in the method can be lowered, and the manufacture cost can be reduced accordingly.

### BACKGROUND OF THE INVENTION

### 1. Field of the Invention

The present invention relates to the semiconductor manufacture, and more particularly to a manufacture of monocrystalline silicon ingot by using Czochralski method.

### 2. Description of the Related Art

Czochralski method (CZ method) is widely applied to manufacture monocrystalline silicon materials. Generally, a quartz crucible is used for carrying the melt of the monocrystalline silicon. In CZ method, a seed crystal having predetermined orientation is immersed in the melt, the seed crystal and the melt are rotated in different directions, the seed crystal is slowly pulled upwards, the melt is also pulled along with the seed crystal because of surface tension, and then the continuous single-crystal is formed by cooling of the melt. Since high temperature is requested for several hours in CZ method, the quartz crucible must have high mechanical strength, stable chemical properties and stable thermal stress deformation to prevent plastic deformation due to the heat. Moreover, a larger volume a quartz crucible has, a larger mass of the melt is carried, so that the melting time of the melt is longer.

In CZ method for growing monocrystalline silicon, oxygen may enter monocrystalline silicon because of the melt of quartz crucible. The oxygen mainly exists in silicon lattice space and precipitates when the concentration exceeds beyond its solubility in silicon, the oxygen precipitation defect is formed thereby. The oxygen precipitation defect may damage the integrated circuit device.

Intrinsic gettering technology means that a clean zone with a certain depth having none of defects can be formed on the surface of silicon wafer by generating high density oxygen precipitation within the silicon wafer. The clean zone can be used for device manufacture. However, smaller character size is requested with development of ultra-large-scale integrated circuit (ULSI), so that the oxygen concentration in the monocrystalline silicon has to be reduced to prevent defect formation in the source area. Recently, since thermal budget of integrated circuit manufacture process is significantly reduced, it cannot provide suitable conditions for oxygen precipitation within the silicon wafer and the intrinsic gettering effect is adversely affected.

The above problems can be solved by nitrogen doping during growth of monocrystalline silicon in Czochralski method. Nitrogen is able to facilitate oxygen precipitation within monocrystalline silicon, therefore the intrinsic gettering effect can be enhanced. Further, nitrogen doping is able to increase mechanical strength of the silicon wafer and reduce void defect. Distribution of oxygen precipitation is studied by infrared light scattering tomography (IR-LST) and scanning infrared microscopy (SIRM). It shows that, after one-step thermal annealing of a nitrogen doped 300 mm silicon wafer with suitable nitrogen doping concentration, a high density oxygen precipitation can be generated and a clean zone with a certain depth can be formed near the surface of the wafer. Further, with the increasing nitrogen concentration, the radial distribution of oxygen precipitation becomes more homogeneous.

Hydrogen passivation has become a well-known and established practice in the fabrication of semiconductor devices. Hydrogen passivation is able to eliminate defects of semiconductor devices caused by dangling bonds. Introduction of dangling bonds may reduce charged carriers in the energy gap or add unwanted charge carriers in the device. While dangling bonds occur primarily at surfaces or interfaces in the device, they also are thought to occur at vacancies, micropores, dislocations, and also to be associated with impurities. FIG. 1 illustrates a reaction-diffusion model, in which Si—H bonds break at Si/SiO₂ interface to generate an electric-activation interface while hydrogens are released and diffuse into the dielectric layer.

U.S. Pat. No. 5,872,387 discloses a process for conditioning a semiconductor device by using deuterium to reduce depassivation problems. The semiconductor device comprises a semiconductor layer of elements of Group III, Group IV, Group V or any mixture thereof, and an insulating layer (dielectric layer) formed on the semiconductor layer. Deuterium atoms are able to covalently bind to the Group III, Group IV or Group V elements to significantly reduce the hot carrier effects of the semiconductor device.

U.S. Pat. No. 6,319,313 discloses a process for preparing doped molten silicon for use in a single silicon crystal ingot growing process. The process comprises charging polysilicon and barium dopant to a crucible having a bottom wall and a sidewall formation, and the crucible containing less than about 0.5% gases insoluble in silicon; melting the polysilicon to form a mass of molten silicon in the crucible; and forming a silica layer on the inside surface of the crucible in contact with the molten mass. The silica layer is nucleated by the barium in the molten mass. The barium dopant may be barium oxide, barium silicate, barium acetate, barium silicide, barium hydride, barium chloride, barium oxalate, barium carbonate, barium silicon oxide, and/or an alloy of polysilicon and barium. However, it is difficult to practice because the barium dopant has to be added in a very precise amount. Moreover, it is impossible to control the formation of silica layer because the barium dopant is homogeneously dispersed on the crucible surface.

Therefore, there is a need for a method of growing monocrystalline silicon by using CZ method that can reduce defects of monocrystalline silicon, prevent penetration of hot carriers, enhance device reliability, and overcome at least the aforementioned issues.

### SUMMARY

The present application describes a method for growing monocrystalline silicon by using Czochralski method, comprising: step (1) melting a deuterium-, nitrogen- and barium-doped silicon sheet and a polycrystalline silicon in a crucible; and step (2) forming a deuterium- and nitrogen-doped monocrystalline silicon ingot by using magnetic field-applied Czochralski method.

### BRIEF DESCRIPTION OF THE DRAWINGS

FIG. 1 illustrates a reaction-diffusion model of the well-known hydrogen passivation, in which Si—H bonds break at Si/SiO₂ interface to generate an electric-activation interface containing numerous dangling bonds while hydrogens are released and diffuse into the dielectric layer,

FIG. 2 illustrates a reaction-diffusion model of the deuterium-doped wafer of the present application, in which deuterium atoms diffuse out and bind with dangling bonds at the interface between a gate dielectric layer and a semiconductor to form a stable structure,

FIG. 3 is a flowchart illustrating a process for growing monocrystalline silicon by using Czochralski method according to one embodiment of the present application, and

FIG. 4 is a flowchart illustrating a process for growing monocrystalline silicon by using Czochralski method according to one embodiment of the present application.

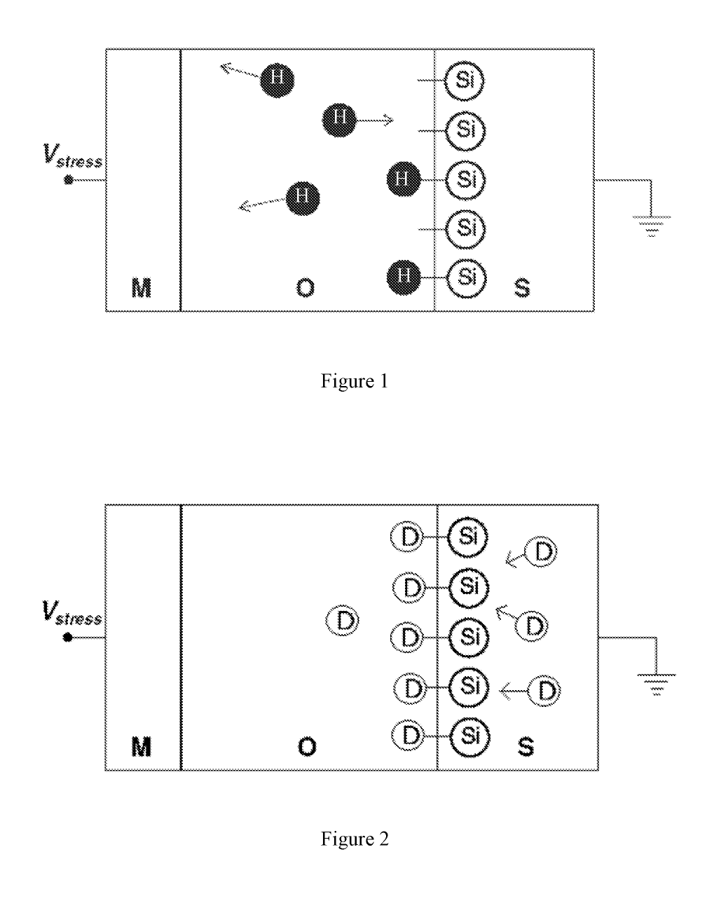

### DETAILED DESCRIPTION OF THE EMBODIMENTS

The present application provides a method for growing monocrystalline silicon by using Czochralski method, which is able to solve the problems caused by conventional processes including more defects of grown monocrystalline silicon, severe hot carrier effects and the like.

In the present application, the method for growing monocrystalline silicon by using Czochralski method, comprising: step (1) melting a deuterium-, nitrogen- and barium-doped silicon sheet and a polycrystalline silicon in a crucible; and step (2) forming a deuterium- and nitrogen-doped monocrystalline silicon ingot by using magnetic field-applied Czochralski method.

In one preferred embodiment, while the silicon sheet and the polycrystalline silicon are put into the crucible, a gas is fed simultaneously. The gas contains argon.

In one preferred embodiment, the step (1) further comprises preparing the deuterium-, nitrogen- and barium-doped silicon sheet by forming a film of silicon nitride on a surface of the silicon sheet, and doping deuterium and barium ions to the silicon sheet by ion implantation.

Preferably, the ion implantation of deuterium is conducted at an implantation energy of 1 KeV˜1000 KeV and an implantation dosage of 1×10¹²-1×10¹⁸ ions/cm². The ion implantation of barium is conducted at an implantation energy of 1 KeV˜1000 KeV and an implantation dosage of 1×10¹²-1×10¹⁸ ions/cm².

In one preferred embodiment, the step (1) further comprises preparing the deuterium-, nitrogen- and barium-doped silicon sheet by doping deuterium, nitrogen and barium ions to the silicon sheet by ion implantation.

Preferably, the ion implantation of deuterium is conducted at an implantation energy of 1 KeV˜1000 KeV and an implantation dosage of 1×10¹²-1×10¹⁸ ions/cm². The ion implantation of nitrogen is conducted at an implantation energy of 1 KeV˜1000 KeV and an implantation dosage of 1×10¹²-1×10¹⁸ ions/cm². The ion implantation of barium is conducted at an implantation energy of 1 KeV˜1000 KeV and an implantation dosage of 1×10¹²-1×10¹⁸ ions/cm².

In one preferred embodiment, the silicon sheet and the polycrystalline silicon are melted at a temperature between 900° C. and 2000° C.

In one preferred embodiment, during the melting step, the barium acts as an accelerant for formation of an opaque silicon dioxide layer at an interface between the crucible and the melt, so that a concentration of impurities contained in the melt and the grown crystal can be reduced.

In one preferred embodiment, the magnetic field-applied Czochralski method comprises: step (2-1) applying a magnetic field to the crucible carrying the melt of the deuterium-, nitrogen- and barium-doped silicon sheet and the polycrystalline silicon; step (2-2) pulling a crystal rod upward by a predetermined pulling rate from a crystal seed until reaching a predetermined length of the crystal rod; step (2-3) reducing the pulling rate and maintaining a linear cooling rate to form a monocrystalline silicon ingot with a predetermined diameter, and conducting shoulder and body growing steps.

In one preferred embodiment, in the monocrystalline silicon ingot, the concentration of the nitrogen atom is 1×10¹³˜1×10¹⁶ atoms/cm³, and the concentration of the deuterium atom is 1×10¹²˜1×10¹⁸ atoms/cm³.

According to the above, the present application provides the following advantages.

The barium-doped silicon sheet and the polycrystalline silicon are melted and mixed to form a melt, then an opaque silicon dioxide layer is formed on the inner surface of the crucible which contacts to the melt. During the crystal growth, the opaque silicon dioxide layer is able to reduce the impurities contained in the melt and the grown crystal.

By applying rapid thermal annealing (RTA) to the nitrogen-doped monocrystalline silicon sheet, crystal originated particle (COP) defects in 0.5 micrometer depth surface area of the silicon sheet can be eliminated. The COP density of the surface layer can be reduced to about 50% or less than that of the block body. Moreover, there is no bulk micro defect (BMD) on the silicon sheet surface.

In the present application, the melt of silicon materials contains deuterium. The storage of deuterium atoms in gaps of the monocrystalline silicon ingot is able to reduce the contents of oxygen and carbon impurities. By applying the method of the present application, the obtained monocrystalline silicon ingot can be used to fabricate a wafer. During formation of a device on the wafer, the deuterium atoms can diffuse out and bind with dangling bonds at the interface between a gate dielectric layer and a semiconductor to form a stable structure, thereby penetration of hot carriers can be prevented, leakage current can be reduced, and device properties and reliability can be enhanced.

Moreover, in the present application, the silicon sheet is doped with deuterium, nitrogen and barium, the amount of the doped silicon sheet applied in the method can be lowered, and the manufacture cost can be reduced accordingly.

### EXAMPLES

### Example 1

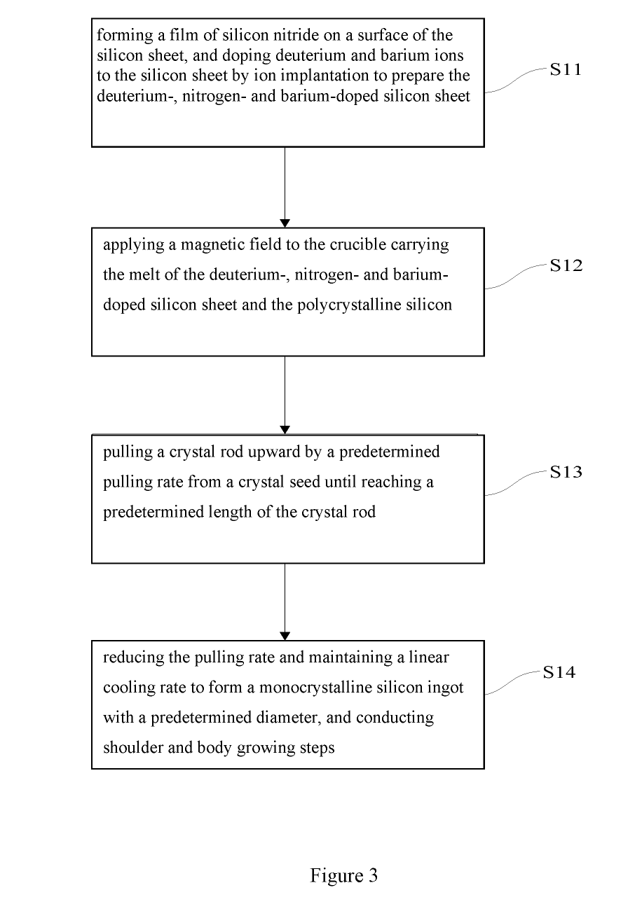

Referring to FIG. 2 and FIG. 3, the process for growing monocrystalline silicon by using Czochralski method is provided and described as follows.

In initial step S11, the deuterium-, nitrogen- and barium-doped silicon sheets and polycrystalline silicon materials are provided. The materials are put in a crucible, and, at the same time a gas comprising argon is fed into the crucible. Then the materials are melted.

In this example, the deuterium-, nitrogen- and barium-doped silicon sheet is prepared by forming a thin film of silicon nitride on a surface of the silicon sheet, and then doping deuterium and barium ions to the silicon sheet by ion implantation.

Deuterium ions and barium ions can be doped into the silicon sheet separately or simultaneously. In this example, the ion implantation of deuterium is conducted at an implantation energy of 1 KeV˜1000 KeV and an implantation dosage of 1×10¹²-1×10¹⁸ ions/cm². The ion implantation of barium is conducted at an implantation energy of 1 KeV˜1000 KeV and an implantation dosage of 1×10¹²-1×10¹⁸ ions/cm².

By adjusting the film thickness of silicon nitride as well as the implantation dosages of deuterium and barium ions, the doping amount of the doped ion in the silicon sheet can be precisely controlled. It significantly improves the precision and the controllability of ion doping in the final melt.

The temperature for melting the silicon sheets and the polycrystalline silicon is, for example, about 900 to about 2000° C. The temperature should be higher than the melting point of silicon nitride, so that the silicon nitride is able to fully melt, and the silicon materials can be mixed homogeneously to from the melt.

During the melting step, the barium acts as an accelerant for formation of an opaque silicon dioxide layer at an interface between the crucible and the melt, so that a concentration of impurities contained in the melt and the grown crystal can be reduced.

Then, the magnetic field-applied Czochralski method is applied to form a deuterium- and nitrogen-doped monocrystalline silicon ingot.

The magnetic field-applied Czochralski method includes the following steps. In step S12, a magnetic field is applied to the crucible carrying the melt of the deuterium-, nitrogen- and barium-doped silicon sheet and the polycrystalline silicon. In step S13, a crystal rod is pulled upward by a predetermined pulling rate from a crystal seed until reaching a predetermined length of the crystal rod. In step S14, the pulling rate is reduced and a linear cooling rate is maintained to form a monocrystalline silicon ingot having a predetermined diameter. Then shoulder and body growing steps are conducted.

In one embodiment of implementation, the deuterium- and barium-doped silicon sheets containing silicon nitride grown on the surface and polysilicon bulks are well mixed and melted under the temperature exceeding the melting point of silicon nitride, e.g. 1900° C. to 2000° C. Then the melt is cooled and seeded by the crystal seed. At this time point, the central area of the melt surface is at the temperature of silicon melting point. Then the solid-phase nitrogen doping step and the crystal pulling growth can be performed. The crystal rod is pulled upward by a predetermined pulling rate from a crystal seed until reaching a predetermined length of the crystal rod. The pulling rate is reduced, and the linear cooling rate is maintained to form the monocrystalline silicon ingot with a predetermined diameter. While the monocrystalline silicon ingot has the predetermined diameter, the pulling rate is immediately increased, and the temperature is simultaneously cooled down. Simultaneously, the linear cooling step is terminated. The rising rate of the crucible is controlled. According to the change rate of the diameter of the monocrystalline silicon ingot, the pulling rate is slowly adjusted to stabilize the diameter of the monocrystalline silicon ingot, and continuously grow the monocrystalline silicon ingot. Automatic diameter-controlling program is applied to monitor the ingot growth. The deuterium- and nitrogen-doped monocrystalline silicon ingot is finally obtained.

By applying the method of the present application, it is able to precisely control the concentrations of deuterium and nitrogen in the silicon ingot and achieve excellent doping homogeneity. In the obtained silicon ingot and the silicon wafer, the concentration of the nitrogen atom is 1×10¹³ ˜1×10¹⁶ atoms/cm³, and the concentration of the deuterium atom is 1×10¹²˜1×10¹⁸ atoms/cm³.

By applying rapid thermal annealing (RTA) to the nitrogen-doped monocrystalline silicon sheet, crystal originated particle (COP) defects in 0.5 micrometer depth surface area of the silicon sheet can be eliminated. The COP density of the surface layer can be reduced to about 50% or less than that of the block body. Moreover, there is no bulk micro defect (BMD) on the silicon sheet surface.

As shown in FIG. 2, deuterium is added into the melt of silicon materials, so that the deuterium atoms are stored in gaps of the monocrystalline silicon ingot. The stored deuterium is able to reduce the contents of oxygen and carbon impurities. By applying the method of the present application, the obtained monocrystalline silicon ingot can be used to fabricate a wafer. During formation of a device on the wafer, the deuterium atoms can diffuse out and bind with dangling bonds at the interface between a gate dielectric layer and a semiconductor to form a stable structure, thereby penetration of hot carriers can be prevented, leakage current can be reduced, and device properties and reliability can be enhanced.

### Example 2

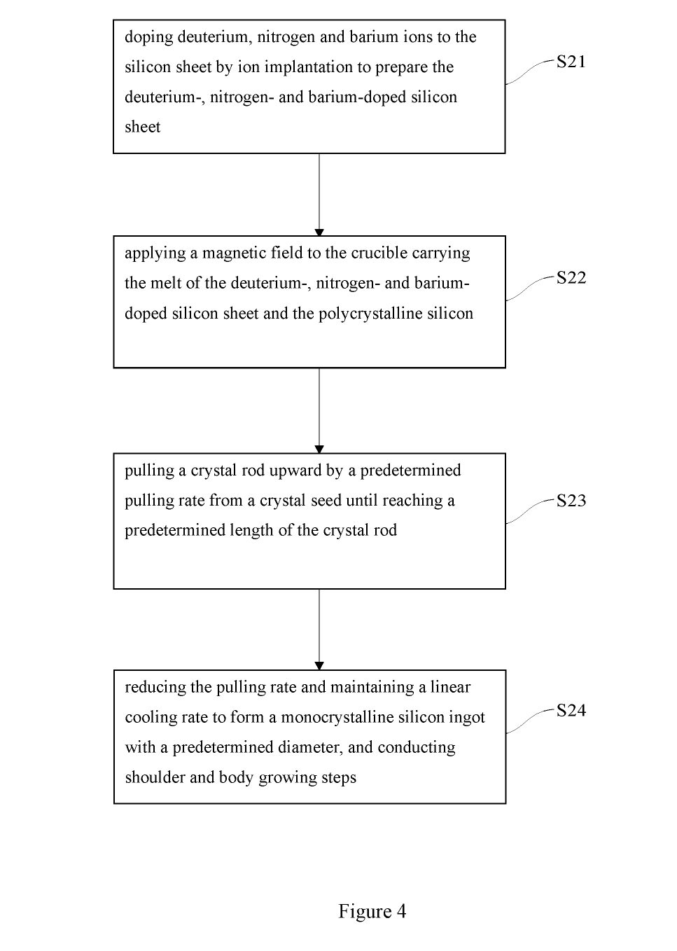

Referring to FIG. 4, in this example, the process for growing monocrystalline silicon by using Czochralski method is performed like Example 1 except the step S21.

In step S21, the deuterium-, nitrogen- and barium-doped silicon sheet is prepared by doping deuterium, nitrogen and barium ions to the silicon sheet by ion implantation. In this example, deuterium ions, nitrogen atoms and barium ions can be doped into the silicon sheet separately or simultaneously. The ion implantation of deuterium is conducted at an implantation energy of 1 KeV˜1000 KeV and an implantation dosage of 1×10¹²-1×10¹⁸ ions/cm². The ion implantation of nitrogen is conducted at an implantation energy of 1 KeV˜1000 KeV and an implantation dosage of 1×10¹²-1×10¹⁸ ions/cm². The ion implantation of barium is conducted at an implantation energy of 1 KeV˜1000 KeV and an implantation dosage of 1×10¹²-1×10¹⁸ ions/cm².

The following steps (S22, S23 and S24) are substantially identical to that of Example 1.

According to the above, the present application provides the following advantages.

The barium-doped silicon sheet and the polycrystalline silicon are melted and mixed to form a melt, then an opaque silicon dioxide layer is formed on the inner surface of the crucible which contacts to the melt. During the crystal growth, the opaque silicon dioxide layer is able to reduce the impurities contained in the melt and the grown crystal.

By applying rapid thermal annealing to the nitrogen-doped monocrystalline silicon sheet, COP defects in 0.5 micrometer depth surface area of the silicon sheet can be eliminated. The COP density of the surface layer can be reduced to about 50% or less than that of the block body. Moreover, there is no BMD on the silicon sheet surface.

In the present application, the melt of silicon material contains deuterium, so that the deuterium atoms are stored in gaps of the monocrystalline silicon ingot, and the contents of oxygen and carbon impurities can be reduced. Moreover, the deuterium atoms can bind with dangling bonds at the interface between the gate dielectric layer and the semiconductor to form a stable structure, thereby penetration of hot carriers can be prevented, leakage current can be reduced, and device properties and reliability can be enhanced.

In the present application, the silicon sheet is doped with deuterium, nitrogen and barium ions, so that the use amount of the doped silicon sheet can be lowered, and the manufacture cost can be reduced accordingly.

Accordingly, the present application overcomes the disadvantages existed in conventional techniques, and has an excellent industrial applicability.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims and its equivalent systems and methods.

What is claimed is:

1. A method for growing monocrystalline silicon by using Czochralski method, comprising:
step (1): melting a deuterium-, nitrogen- and barium-doped silicon sheet and a polycrystalline silicon in a crucible; and
step (2): forming a deuterium- and nitrogen-doped monocrystalline silicon ingot by using magnetic field-applied Czochralski method.

2. The method of claim 1 further comprises feeding a gas containing argon simultaneously with the silicon sheet and the polycrystalline silicon into the crucible.

3. The method of claim 1, wherein the step (1) further comprises preparing the deuterium-, nitrogen- and barium-doped silicon sheet by:
forming a film of silicon nitride on a surface of the silicon sheet, and
doping deuterium and barium ions to the silicon sheet by ion implantation.

4. The method of claim 3, wherein the deuterium ion implantation includes an implantation energy of 1 KeV˜1000 KeV and an implantation dosage of 1×10¹²-1×10¹⁸ ions/cm²; and the barium ion implantation includes an implantation energy of 1 KeV˜1000 KeV and an implantation dosage of 1×10¹²-1×10¹⁸ ions/cm².

5. The method of claim 1, wherein the step (1) further comprises preparing the deuterium-, nitrogen- and barium-doped silicon sheet by doping deuterium, nitrogen and barium ions to the silicon sheet by ion implantation.

6. The method of claim 5, wherein the deuterium ion implantation includes an implantation energy of 1 KeV˜1000 KeV and an implantation dosage of 1×10¹²-1×10¹⁸ ions/cm²; the nitrogen ion implantation includes an implantation energy of 1 KeV˜1000 KeV and an implantation dosage of 1×10¹²-1×10¹⁸ ions/cm²; and the barium ion implantation includes an implantation energy of 1 KeV˜1000 KeV and an implantation dosage of 1×10¹²-1×10¹⁸ ions/cm².

7. The method of claim 1, wherein in the step (1), the melting temperature is between 900° C. and 2000° C.

8. The method of claim 1, wherein in the step (1), the barium acts as an accelerant for formation of an opaque silicon dioxide layer between the crucible and the melt, so that a concentration of impurities contained in the melt and the grown crystal is reduced.

9. The method of claim 1, wherein the magnetic field-applied Czochralski method comprises:
step (2-1): applying a magnetic field to the crucible carrying the melt of the deuterium-, nitrogen- and barium-doped silicon sheet and the polycrystalline silicon;
step (2-2): pulling a crystal rod upward by a predetermined pulling rate from a crystal seed until reaching a predetermined length of the crystal rod; and
step (2-3): reducing the pulling rate and maintaining a linear cooling rate to form a monocrystalline silicon ingot with a predetermined diameter, and conducting shoulder and body growing steps.

10. The method of claim 1, wherein the monocrystalline silicon ingot comprises a nitrogen concentration of 1×10¹³ ˜1×10¹⁶ atoms/cm³ and a deuterium concentration of 1×10¹²˜1×10¹⁸ atoms/cm³.
